(19) United States
(12) Patent Application Publication
(10) Pub. No.: US 2019/0352765 A1
(43) Pub. Date: Nov. 21, 2019

(54) DEPOSITION MASK

(71) Applicant: Japan Display Inc., Minato-ku (JP)

(72) Inventors: Keisuke ONO, Minato-ku (JP); Atsushi TAKEDA, Minato-ku (JP); Tetsuyuki YAMADA, Minato-ku (JP); Mototsugu NARIYA, Minato-ku (JP); Mitsugu TAMEKAWA, Minato-ku (JP); Takeshi OOKAWARA, Minato-ku (JP); Naoto HIRASAKA, Minato-ku (JP); Taiki WATANABE, Minato-ku (JP)

(73) Assignee: Japan Display Inc., Minato-ku (JP)

(21) Appl. No.: 16/527,717

(22) Filed: Jul. 31, 2019

Related U.S. Application Data
(63) Continuation of application No. PCT/JP2017/039056, filed on Oct. 30, 2017.

(30) Foreign Application Priority Data
Feb. 10, 2017 (JP) 2017-022875

(51) Int. Cl. C23C 14/04; C25D 1/10; C23C 14/34

(52) U.S. Cl. CPC C23C 14/042; H01L 51/0011; C23C 14/34; C25D 1/10

(57) ABSTRACT

A deposition mask according to an embodiment of the present invention includes: a mask main body including a pattern portion formed with a pattern opening, and a frame portion surrounding the pattern portion; a mask frame supporting the frame portion of the mask main body; and an intermediate member having a shape corresponding to the mask frame, the intermediate member being disposed between the mask main body and the mask frame. The mask main body and a first face of the intermediate member are joined together, and the mask frame and a face of the intermediate member on the side opposite to the first face are joined together.

### CROSS-REFERENCE TO RELATED APPLICATIONS

This application is a continuation under 35 U.S.C. 120 of International Application PCT/JP2017/039056 having the International Filing Date of Oct. 30, 2017, and having the benefit of the earlier filing date of Japanese Application No. 2017-022875, filed on Feb. 10, 2017. Each of the identified applications is fully incorporated herein by reference.

### BACKGROUND OF THE INVENTION

### 1. Field of the Invention

One or more embodiments of the present invention relate to a deposition mask.

### 2. Description of the Related Art

In the manufacture of a display device such as an organic electro luminescent (EL) display device, a technique to perform deposition by depositing a deposition material at a predetermined position on a substrate via a mask by a vapor deposition method or the like is generally used. For example, organic EL elements (pixels) of red, green, and blue are formed on a substrate by a vapor deposition method using a mask. In the mask used in this case, an opening corresponding to a pattern to be deposited is formed (e.g., see JP 2004-039628 A and JP 2004-183023 A).

### SUMMARY OF THE INVENTION

However, in the deposition using the mask, for example, there is a problem in that the pattern to be obtained is blurred.

One or more embodiments of the invention have been made in view of the above, it is an object thereof to provide a deposition mask by which high-precision pattern deposition can be realized.

A deposition mask according to an embodiment of the invention includes: a mask main body including a pattern portion formed with a pattern opening, and a frame portion surrounding the pattern portion; a mask frame supporting the frame portion of the mask main body; and an intermediate member (also called join member) having a shape corresponding to the mask frame, the intermediate member being disposed between the mask main body and the mask frame. The mask main body and a first face of the intermediate member are joined together, and the mask frame and a face of the intermediate member on the side opposite to the first face are joined together.

In one embodiment of the invention, the mask frame holds a plurality of the mask main bodies.

In one embodiment of the invention, the mask main body is an electroformed mask.

In one embodiment of the invention, the joining is made by welding.

In one embodiment of the invention, a thickness of the intermediate member is from 0.05 mm to 0.2 mm.

In one embodiment of the invention, a ratio of a thickness of the intermediate member to a thickness of the mask frame is from 0.005 to 0.1.

In one embodiment of the invention, a ratio of a thickness of the intermediate member to a thickness of the frame portion is from 0.2 to 0.4.

In one embodiment of the invention, the pattern portion corresponds to a panel portion of a display device to be manufactured.

### BRIEF DESCRIPTION OF THE DRAWINGS

FIG. 1 is an external perspective view of a deposition mask in a first embodiment of the invention.

FIG. 2 is an exploded perspective view of the deposition mask shown in FIG. 1.

FIG. 3 is a cross-sectional view taken along line A-A of FIG. 1.

FIG. 4 is a schematic cross-sectional view showing a usage example of the deposition mask shown in FIG. 1.

FIG. 5 is a plan view showing a mask frame of a deposition mask in a second embodiment of the invention.

FIG. 6 is a plan view showing a mask frame of a deposition mask in a third embodiment of the invention.

### DETAILED DESCRIPTION OF THE INVENTION

Hereinafter, embodiments of the invention will be described with reference to the drawings. The disclosure is illustrative only. Appropriate modifications that will readily occur to those skilled in the art and fall within the spirit of the invention are of course included in the scope of the invention. In the drawings, for more clarity of description, the width, thickness, shape, and the like of each part may be schematically represented compared to those in an actual form. However, they are illustrative only, and do not limit the interpretation of the invention. Moreover, in the specification and the drawings, elements similar to those described in relation to a previous drawing are denoted by the same reference numerals and signs, and a detailed description may be appropriately omitted.

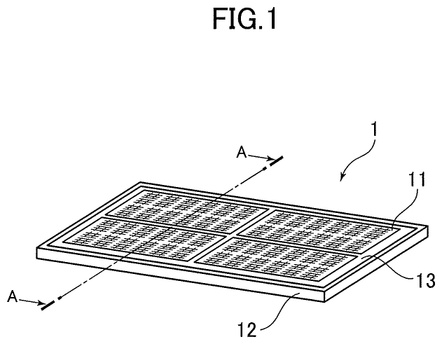

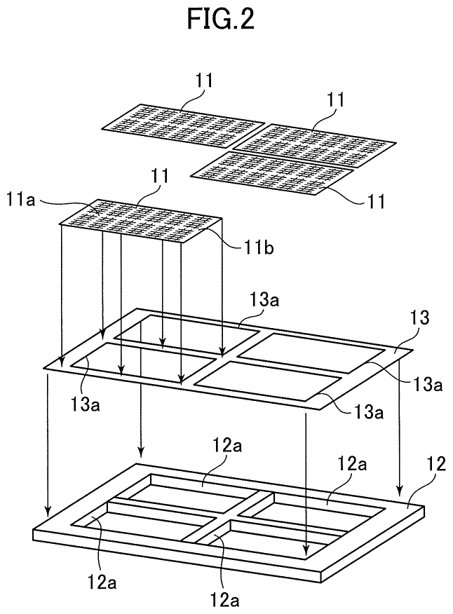

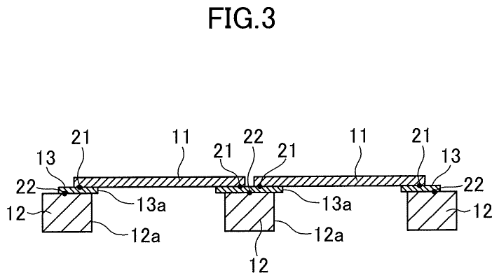

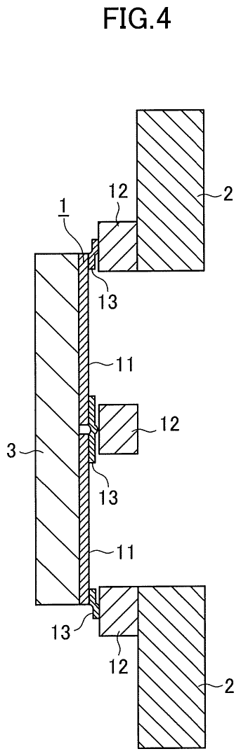

FIG. 1 is an external perspective view of a deposition mask in a first embodiment of the invention. FIG. 2 is an exploded perspective view of the deposition mask shown in FIG. 1. FIG. 3 is a cross-sectional view taken along line A-A of FIG. 1. FIG. 4 is a schematic cross-sectional view showing a usage example of the deposition mask shown in FIG. 1.

The deposition mask 1 includes a mask main body 11, a mask frame 12 supporting the mask main body 11, and an intermediate member 13 disposed between the mask main body 11 and the mask frame 12. Each member is formed of, for example, metal (e.g., Invar).

The mask main body 11 includes a pattern portion 11a formed with a pattern opening, and a frame portion 11b surrounding the pattern portion 11a. The mask main body 11 is supported by the mask frame 12 at the frame portion 11b. The shape and the pattern opening of the pattern portion 11a are made to correspond to, for example, a panel portion of a display device to be manufactured. Specifically, the pattern opening of the pattern portion 11a is made to correspond to a pattern of a light-emitting layer of a panel portion of an organic EL display device to be manufactured.

The pattern portion 11a can be formed by any proper method. Specifically, the pattern portion 11a may be formed by electroforming, or may be formed by etching. In the embodiment, the pattern portion 11a includes a plated portion (e.g., Ni-plated portion) formed by electroforming, and the mask main body 11 is an electroformed mask. According to the electroformed mask, for example, higher-precision pattern deposition can be achieved. The thickness of the pattern portion 11a is, for example, from 5 μm to 20 μm. The thickness of the frame portion 11b is, for example, from 0.5 mm to 1 mm.

In the embodiment, in the mask frame 12, a total of four window portions 12a, two in the vertical direction and two in the horizontal direction, each corresponding to the shape of the mask main body 11 are formed. By causing the mask frame 12 to support a plurality of mask main bodies 11 as described above, an existing mask main body 11 can be used also for, for example, a form in which the size of a substrate as a deposition object is larger than that of the mask main body 11. The size of the window portion 12a of the mask frame 12 is designed so as to be larger than that of the pattern portion 11a of the mask main body 11. The thickness of the mask frame 12 is, for example, from 2 mm to 10 mm.

The intermediate member 13 has a shape corresponding to the mask frame 12. Specifically, four window portions 13a are formed in the intermediate member 13, and the size of the window portion 13a is designed so as to be larger than that of the pattern portion 11a of the mask main body 11 and smaller than that of the window portion 12a of the mask frame 12.

The mask main body 11 and the mask frame 12 are integrated via the intermediate member 13. Specifically, the mask main body 11 and the intermediate member 13 are joined together, and the mask frame 12 and the intermediate member 13 are joined together, so that the mask main body 11 and the mask frame 12 are integrated together. By causing the intermediate member 13 to intervene therebetween as described above, the rigidity of the entire deposition mask 1 can be lowered. Specifically, the rigidity of the entire deposition mask 1 can be lower than that of the mask main body 11 alone. As a result, even when the rigidity of the substrate as a deposition object is high, the intrusion of a deposition material between the deposition mask 1 and the substrate can be suppressed by improving the adhesion of the deposition mask 1 to the substrate, and high-precision pattern deposition can be realized.

The mask main body 11 is joined to the intermediate member 13 by, for example, welding (e.g., laser welding). The intermediate member 13 is joined to the mask frame 12 by, for example, welding (e.g., laser welding). The arrangement, number, and the like of joining points can be appropriately determined. FIG. 3 shows the joining points, in which a joining portion 22 of the intermediate member 13 and the mask frame 12 is disposed to be spaced outwardly from the mask main body 11 with respect to a joining portion 21 of the mask main body 11 and the intermediate member 13. By spacing the joining portions apart from each other as described above, flexure occurs in the intermediate member 13 as shown in FIG. 4, and the adhesion of the deposition mask 1 to the substrate as a deposition object can be further improved.

The thickness of the intermediate member 13 is set so as to be thinner than the thickness of the mask main body 11 (the frame portion 11b). The thickness of the intermediate member 13 is preferably from 0.05 mm to 0.2 mm. The ratio of the thickness of the intermediate member 13 to the thickness of the mask frame 12 is preferably from 0.005 to 0.1. The ratio of the thickness of the intermediate member 13 to the thickness of the frame portion 11b of the mask main body 11 is preferably from 0.2 to 0.4. According to the form described above, it is possible to favorably achieve both the lowering of rigidity of the deposition mask 1 to be obtained and the fixing strength of the intermediate member 13 to the mask main body 11 and the mask frame 12.

As shown in FIG. 4, the deposition mask 1 held by a pin or the like to a conveying frame 2 from the mask frame 12 side is disposed so as to face a deposition surface of a substrate 3 as a deposition object. In this state, a deposition material is deposited onto the substrate 3 from the deposition mask 1 side by, for example, vapor deposition, sputtering, or the like. In the example shown in the drawing, for example, the substrate 3 is vertically disposed from the viewpoint of effectively using a manufacturing space. Also in the form described above, the adhesion of the deposition mask 1 to the substrate 3 can be ensured. Although not shown in the drawing, deposition may be performed on the substrate 3 on the surface of which a predetermined layer is previously formed. Moreover, although not shown in the drawing, the substrate 3 may be supported by a support plate in deposition.

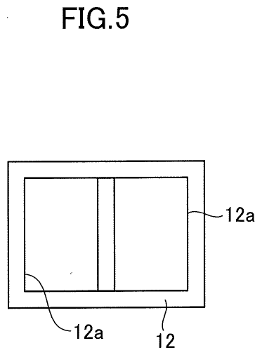

FIG. 5 is a plan view showing a mask frame of a deposition mask in a second embodiment of the invention. The embodiment differs from the first embodiment in that the mask frame 12 is divided into two portions with an increase in the size of the mask main body and thus two window portions 12a each corresponding to the mask main body are formed.

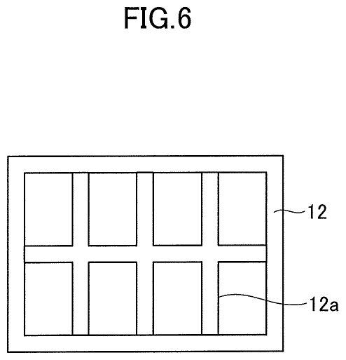

FIG. 6 is a plan view showing a mask frame of a deposition mask in a third embodiment of the invention. The embodiment differs from the first embodiment in that the size of the mask frame 12 is increased with an increase in the size of a substrate as a deposition object and thus eight window portions 12a each corresponding to the mask main body are formed.

The invention is not limited to the embodiments, and various modifications can be made. For example, any configuration shown in the embodiments can be replaced with substantially the same configuration as that shown in the embodiments, a configuration providing the same operational effect, or a configuration capable of achieving the same object.

Various altered and modified examples within the range of the idea of the invention will occur to those skilled in the art, and it should be understood that the altered and modified examples also belong to the scope of the invention. For example, when those skilled in the art appropriately add or remove a component or change the design of a component in each of the embodiments described above, or add or omit a step or change the conditions of a step in each of the embodiments described above, those are included in the scope of the invention as long as they include the spirit of the invention.

What is claimed is:

1. A deposition mask comprising:
a mask main body including a pattern portion formed with a pattern opening, and a frame portion surrounding the pattern portion;
a mask frame supporting the frame portion of the mask main body; and
an intermediate member having a shape corresponding to the mask frame, the intermediate member being disposed between the mask main body and the mask frame, wherein
the mask main body and a first face of the intermediate member are joined together, and the mask frame and a face of the intermediate member on the side opposite to the first face are joined together.

2. The deposition mask according to claim 1, wherein
the mask frame holds a plurality of the mask main bodies.

3. The deposition mask according to claim 1, wherein
the mask main body is an electroformed mask.

4. The deposition mask according to claim 1, wherein
the joining is made by welding.

5. The deposition mask according to claim 1, wherein
a thickness of the intermediate member is from 0.05 mm to 0.2 mm.

6. The deposition mask according to claim 1, wherein
a ratio of a thickness of the intermediate member to a thickness of the mask frame is from 0.005 to 0.1.

7. The deposition mask according to claim 1, wherein
a ratio of a thickness of the intermediate member to a thickness of the frame portion is from 0.2 to 0.4.

8. The deposition mask according to claim 1, wherein
the pattern portion corresponds to a panel portion of a display device to be manufactured.
